(19) United States
(12) Patent Application Publication
(10) Pub. No.: US 2002/0074242 A1
(43) Pub. Date: Jun. 20, 2002

(54) Seed layer recovery

(75) Inventors: Denis Morrissey, Huntington, NY (US); Jeffrey M. Calvert, Action, MA (US); Rozalia Beica, Bayport, NY (US)

Correspondence Address: S. Matthew Cairns, c/o EDWARDS & ANGELL, LLP, Dike, Bronstein, Roberts & Cushman, IP Group, P.O. Box 9169, Boston, MA, 02209, US

(73) Assignee: Shipley Company, L.L.C., Marlborough, MA

(21) Appl. No.: 09/977,596

(22) Filed: Oct. 13, 2001

Related U.S. Application Data
(60) Provisional application No. 60/240,145, filed on Oct. 13, 2000.

(51) Int. Cl. C25F 5/00; C25F 1/00; C30B 30/02

(52) U.S. Cl. 205/704

(57) ABSTRACT

Disclosed is a method for repairing of seed layers by removal of oxidized metal from the seed layers prior to subsequent metallization. Also disclosed is a method for monitoring such repair to provide substantially metal oxide free seed layers.

### BACKGROUND OF THE INVENTION

The present invention relates generally to the field of seed layers for subsequent metallization. In particular, this invention relates to methods for repairing seed layers prior to metallization.

The trend toward smaller microelectronic devices, such as those with sub-micron geometries, has resulted in devices with multiple metallization layers to handle the higher densities. One common metal used for forming metal lines, also referred to as wiring, on a semiconductor wafer is aluminum. Aluminum has the advantage of being relatively inexpensive, having low resistivity, and being relatively easy to etch. Aluminum has also been used to form interconnections in vias to connect the different metal layers. However, as the size of via/contact holes shrinks to the sub-micron region, a step coverage problem appears which in turn can cause reliability problems when using aluminum to form the interconnections between the different metal layers. Such poor step coverage results in high current density and enhances electromigration.

One approach to providing improved interconnection paths in the vias is to form completely filled plugs by using metals such as tungsten while using aluminum for the metal layers. However, tungsten processes are expensive and complicated, tungsten has high resistivity, and tungsten plugs are susceptible to voids and form poor interfaces with the wiring layers.

Copper has been proposed as a replacement material for interconnect metallizations. Copper has the advantages of improved electrical properties as compared to tungsten and better electromigration property and lower resistivity than aluminum. The drawbacks to copper are that it is more difficult to etch as compared to aluminum and tungsten and it has a tendency to migrate into the dielectric layer, such as silicon dioxide. To prevent such migration, a barrier layer, such as titanium nitride, tantalum nitride and the like, must be used prior to the depositing of a copper layer.

Typical techniques for applying a copper layer, such as electrochemical deposition, are only suitable for applying copper to an electrically conductive layer. Thus, an underlying conductive seed layer, typically a metal seed layer such as copper, is generally applied to the substrate prior to electrochemically depositing copper. Such seed layers may be applied by a variety of methods, such as physical vapor deposition (“PVD”) and chemical vapor deposition (“CVD”). Typically, seed layers are thin in comparison to other metal layers, such as from 50 to 1500 angstroms thick. As the apertures to be plated become smaller, the amount of seed layer that can be deposited within the aperture becomes limited. As a result, the normal oxidation of copper by atmospheric oxygen can convert a large percentage of, or even the entire, seed layer within apertures to metal oxide.

Oxide on a metal seed layer, particularly a copper seed layer, interferes with subsequent copper deposition. Such oxide forms from exposure of the metal seed layer to oxygen, such as air. The longer such seed layer is exposed to oxygen, the greater the amount of oxide formation. Where a copper seed layer is thin, the copper oxide may exist as copper oxide throughout the layer. In other areas of electroplating, such as in electronics finishing, copper oxide layers are typically removed by acidic etching baths. These baths dissolve the oxide layer, leaving a copper metal surface. Such etching processes are not generally applicable to copper seed layers because of the thinness of the seed layer. As the oxide is removed from the seed layer surface there is the danger that the entire seed layer may be removed in places, creating discontinuities in the seed layer.

In general, the electrochemical metallization process for advanced interconnects uses a highly conductive sulfuric acid electrolyte (ca. 170 g/L H₂SO₄), cupric sulfate (ca. 17 g/L), and chloride ions (ca. 50-70 mg/L). An organic additive package is used to assist in the development of bottom-up fill, and to promote a uniform thickness of copper across the wafer. Such additive package typically includes accelerators, suppressors and levelers. Exposure of marginally thin copper seed to the highly acidic electrolyte results in removal of the thin conductive copper oxide layer on the seed layer, exposing the underlying agglomerated copper seed layer (“copper islands”). Copper electroplating with traditional chemistry formulations is not adequate for repair of the thin-agglomerated copper seed, and the final fill result contains bottom voids.

U.S. Pat. No. 5,824,599 (Schacham-Diamand et al.) discloses a method of preventing oxide formation on the surface of a copper seed layer by conformally blanket depositing under vacuum a catalytic copper layer over a barrier layer on a wafer and then, without breaking the vacuum, depositing a protective aluminum layer over the catalytic copper layer. The wafer is then subjected to an electroless copper deposition solution which removes the protective aluminum layer exposing the underlying catalytic copper layer and then electrolessly deposits copper thereon. However, such method requires the use of a second metal, aluminum, which adds to the cost of the process and the presence of any unremoved protective layer prior to the electroless deposition of the copper may cause problems in the final product, such as an increase in resistivity. In addition, the dissolved aluminum may build up in the electroless copper bath, which could also cause problems in the final product.

European Patent application EP 1 005 078 A1 (Mikkola et al.) discloses a process for reducing oxidized seed layer to form a recovered seed layer, herein incorporated by reference. In this process, the seed layer containing wafer is placed in an electrolyte bath containing an anode, the wafer being the cathode. The electrolyte bath does not plate metal and thus does not contain copper. The wafer is biased negatively such that a current flows and oxidized components of the seed layer are reduced, forming a deposit composed substantially of zerovalent copper metal. Typically, the bath is operated at a current density in the range of from approximately 0.05 to 500 mA/cm². According to this disclosure, the wafers are subjected to such electrolyte baths for a time sufficient to substantially reduce the oxidized seed to copper metal. Such time will vary depending upon the current density selected. Typically, this recovery process is continued until hydrogen evolution occurs. However, this patent application fails to recognize the importance of complete removal of the oxide from the seed layer and to teach how to monitor the course of the oxide reduction.

The quality of seed layers or the extent of oxide formation in copper seed layers is not monitored in conventional integrated circuit manufacturing processes. Conventionally, the quality of a seed layer is only determined after depositing a metal such as copper on the seed layer and looking for the formation of voids in apertures. If voids are found at this point, the wafer is ruined. The closer such wafer is to a finished integrated circuit, the more time, effort and money will be lost when such wafer is discarded.

There is thus a continuing need for methods of repairing seed layers that remove any surface or bulk oxide formed, that do not require the use of additional metals, that are compatible with commercial metal deposition processes, and that can be controlled such that substantially all of the oxide is removed. There is a further need for monitoring the oxidation state of metal in a seed layer.

### SUMMARY OF THE INVENTION

It has been surprisingly found that the extent of repair or removal of an oxidized seed layer can be monitored according to the present invention.

In one aspect, the present invention provides a method of removing oxidized metal from a metal seed layer including the steps of: a) contacting a metal seed layer containing oxidized metal disposed on a substrate with an aqueous solution having a pH maintained in the range of about 6.5 to about 13; b) subjecting the solution to a voltage of from about 0.1 to 5 volts to reduce the oxidized metal; and c) monitoring the reduction of the oxidized metal to provide a seed layer substantially free of all oxidized metal species.

In a second aspect, the present invention provides a method for manufacturing an electronic device including the steps of: a) contacting a metal seed layer containing oxidized metal disposed on a substrate with an aqueous solution having a pH maintained in the range of about 6.5 to about 13; b) subjecting the solution to a voltage of from about 0.1 to 5 volts to reduce the oxidized metal; c) monitoring the reduction of the oxidized metal to provide a substantially metal oxide free seed layer; and d) contacting the substantially metal oxide free seed layer with an electroplating bath.

In a third aspect, the present invention provides a method for manufacturing an electronic device including the step of monitoring the oxidation state of metal in a seed layer deposited on a substrate.

### BRIEF DESCRIPTION OF THE DRAWING

FIG. 1 shows a plot of voltage versus time during the reduction of copper oxide in a seed layer to copper metal.

### DETAILED DESCRIPTION OF THE INVENTION

As used throughout this specification, the following abbreviations shall have the following meanings, unless the context clearly indicates otherwise: μA/cm²=microamperes per square centimeter; V=volts; ° C.=decrees Centigrade; g/L=gram per liter; cm=centimeter; Å=angstrom; ppm=parts per million and mL=milliliter.

As used throughout the specification, “feature” refers to the geometries on a substrate, such as, but not limited to, trenches and vias. “Apertures” refer to recessed features, such as vias and trenches. The term “small features” refers to features that are one micron or smaller in size. “Very small features” refers to features that are one-half micron or smaller in size. Likewise, “small apertures” refer to apertures that are one micron or smaller in size and “very small apertures” refer to apertures that are one-half micron or smaller in size. As used throughout this specification, the term “plating” refers to metal electroplating, unless the context clearly indicates otherwise. “Deposition” and “plating” are used interchangeably throughout this specification. The term “accelerator” refers to a compound that enhances the plating rate. The term “suppressor” refers to a compound that suppresses the plating rate. “Halide” refers to fluoride, chloride, bromide, and iodide.

All amounts are percent by weight and all ratios are by weight, unless otherwise noted. All numerical ranges are inclusive and combinable.

The present invention provides a method for repairing a metal seed layer disposed on a substrate by substantially removing the oxide from the surface and/or bulk of the seed layer. Suitable substrates for metal seed layers are any which support the metal seed layer. Suitable substrates include, but are not limited to, semiconductor wafers and dielectric layers. Such wafers typically comprise silicon. Dielectric layers, particularly those used in semiconductor manufacture, typically comprises silicon dioxide, silicon carbide, silicon nitride, silicon oxynitride (“SiON”), but may also comprise siloxanes, silsesquioxanes or organic polymers, such as polyarylene ethers, benzocyclobutene, polyimides and the like.

The metal seed layers of the present invention comprise any metal that will subsequently be subjected to metallization, preferably electrolytic metallization. Suitable metal seed layers include, but are not limited to: copper, copper alloys, nickel, nickel alloys, cobalt, cobalt alloys, platinum, platinum alloys, iridium, iridium alloys, palladium, palladium alloys, rhodium, rhodium alloys and the like. It is preferred that the metal seed layer is copper or copper alloy. Such metal seed layers are typically blanket deposited on a substrate.

Any means of blanket depositing the metal seed layer on a substrate may be used. Suitable means include, but are not limited to physical vapor deposition, chemical vapor deposition, and solution deposition such as electroless metal deposition. Physical vapor deposition methods include evaporation, magnetron, and/or rf-diode sputter deposition, ion beam sputter deposition, arc-based deposition, and various plasma-based depositions such as ionized metal plasma. It is preferred that the metal seed layer is deposited by physical vapor deposition, and more preferably by ionized metal plasma deposition. Such metal seed layer deposition methods are generally well known in that art. For example, S. M. Rossnagel, Directional and Ionized Physical Vapor Deposition for Microelectronics Applications, Journal of Vacuum Science Technology, B, volume 16, number 5, pages 2585-2608, September/October 1998, discloses various physical vapor deposition methods and is hereby incorporated by reference to the extent this article teaches the use of such methods.

According to the present invention, metal oxide species contained in the metal seed layer are reduced to the metal. The term “metal oxide contained in the metal seed layer” refers to any metal oxide species on the surface of the seed layer, in the bulk of the seed layer and both on the surface and in the bulk of the seed layer. Such reduction of the metal oxide in the metal seed layer is achieved without the use of etchant solutions. Etchant solutions typically dissolve away the metal oxide, thus providing a metal layer having reduced thickness. For thin metal layers such as seed layers, and particularly for copper seed layers in microelectronic devices having sub-0.5 micron geometries, such dissolution of the metal oxide results in even thinner metal layers and possibly a complete dissolution of the metal layer in places, thereby creating discontinuities. Such discontinuities typically result in the formation of voids upon plating or filling of the apertures. Thus, the present invention provides a method of providing a metal seed layer that is substantially free of metal oxide, without dissolution of the metal oxide. By “substantially free of metal oxide” is meant a metal seed layer where only a small amount of metal oxide is present in the seed layer. It is preferred that the metal seed layer is free of metal oxide.

The metal oxide on the metal seed layer is reduced by contacting the metal seed layer disposed on a substrate with an aqueous solution having a pH maintained in the range of about 6.5 to about 13 and subjecting the aqueous solution to a voltage of from about 0.1 to 5 volts. Such reducing method is referred to herein as “cathodic activation.” It is preferred that the pH of the aqueous solution is maintained in the range of about 7 to about 10, and more preferably in the range of about 7.5 to about 9. Any means for maintaining the pH of the aqueous solution is suitable for use in the present invention. Suitable means include, but are not limited to, the periodic addition of base to the aqueous solution or the use of buffers. The pH of the aqueous solution may be monitored through the use of a pH meter. Such pH monitoring can be automated and the additional base or buffer metered into the aqueous solution as needed to maintain the pH.

Any buffer that maintains a pH in the desired range is suitable for use in the present invention. The buffers may be inorganic or organic. Suitable buffers include, but are not limited to: phosphate, boric acid/borate, tris(hydroxymethyl)aminomethane hydrohalide salt, carbonate and the like. It is preferred that the buffer is selected from phosphate, boric acid/borate and tris(hydroxymethyl)aminomethane hydrohalide salt. The preferred tris(hydroxymethyl)aminomethane hydrohalide salt is tris(hydroxymethyl)aminomethane hydrochloride salt. The buffers are generally prepared by known methods.

The phosphate, borate and carbonate salts of the present invention may be any which are suitable for preparing buffers. Such salts typically include, but are not limited to, the alkali and alkaline earth salts, such as sodium and potassium, ammonium salts, and the like. It will be appreciated by those skilled in the art that phosphate can be used to prepare a buffer solution having a pH in the range of about 6.9 to about 12, depending upon the particular phosphate salts and amounts of such salts employed. All such phosphate buffers are suitable for use in the present invention.

A voltage in the range of about 0.1 to about 5 volts is applied to the aqueous solution to reduce the metal oxide on the surface of the metal seed layer. It is preferred that the voltage is in the range of 0.2 to 5 volts, more preferably 1 to 5 volts, and most preferably 1 to 4 volts. Voltages higher than 5 volts may be successfully employed in the present invention but are generally not needed. The voltage is generally applied to the aqueous solution for a period of time-sufficient to reduce substantially all of the metal oxide to the metal. In general, the voltage is applied to the aqueous solution for 1 to 300 seconds, preferably 15 to 120 seconds, and more preferably 20 to 60 seconds. The voltage may be applied to the aqueous solution by any conventional means, such as through the use of anodes, particularly insoluble anodes, and rectifiers on plating tools. It is preferred that the voltage be applied to the aqueous solution using insoluble anodes, particularly when a copper seed layer is being reduced. Such means will be clear to those skilled in the art.

Typically, the cathodic activation method of the present invention is performed at a temperature in the range of 15° C. to 70° C., and preferably in the range of 20° C. to 60° C. It will be appreciated by those skilled in the art that temperatures outside this range may be successfully used in the present invention, however the length of time the voltage is applied may be different.

The aqueous solutions may optionally contain other components, such as surfactants, particularly nonionic surfactants. It is preferred that when such optional components are used, they are used at low levels. It is further preferred that the aqueous solution of the present invention be free of added metals, more preferably free of transition metals, such as copper, aluminum, cobalt, nickel, tantalum, indium, titanium, and the like, and most preferably free of copper.

The trend toward smaller apertures, such as sub-micron, sub-0.5 micron, and even sub-0.25 micron, makes it more difficult to deposit a seed layer within such apertures. What seed layer is deposited within these apertures is very thin. The normal oxidation of such thin seed layer by exposure to atmospheric oxygen converts a large percentage of, or the entirety of, the metal seed layer to metal oxide. This oxide decreases the conductivity of the seed layer considerably, leading to plating voids within the apertures. Also, when a copper seed layer is used, the copper oxide species are typically soluble in acidic containing electrolytes used for copper plating. This results in a discontinuous seed layer which also leads to plating voids.

The present invention also provides for the monitoring of the reduction of the oxidized metal to provide a seed layer substantially free of all oxidized metal species. Such monitoring allows for the determination of when substantially all, and preferably all, metal oxide has been reduced to zerovalent metal. Thus, the seed layers containing metal oxide are subjected to the cathodic activation treatment described above until substantially all of the metal oxide has been reduced to zerovalent metal.

Monitoring of the reduction shows when the reduction of the metal oxide is substantially complete or preferably complete. Without such monitoring, the seed layer may not be subjected to the cathodic activation treatment for a sufficient length of time to reduce substantially all, or all, of the metal oxide to zerovalent. In the case of a copper seed layer, such remaining copper oxide species reduce the conductivity of the seed layer and may dissolve upon contact with the acidic electrolyte during subsequent electroplating. Thus, voids may result in the final deposit, even though some of the copper oxide in the seed layer had been reduced to copper metal. Alternatively, the seed layer may be subjected to the cathodic activation for a very long period of time to ensure complete reduction of metal oxide species. Such long period of time may be significantly longer than is required to reduce the amount of oxidized metal in a given lot of seed layer containing substrates. This excess contact time with the cathodic activation treatment adversely affects the efficiency of the process, thereby decreasing throughput.

Such monitoring of the metal oxide reduction may be performed by a variety of means, such as by use of a QC-100™ Surface Scan instrument (available from ECI, New Jersey) or any suitable potentiostat. Such monitoring has been used in the printed wiring board industry to monitor oxide in solder joints, but has not been used in the semiconductor industry. Typically, monitoring is achieved by using a potentiostat equipped with a three electrode system, which maintains a small cathodic current on the seed layer containing substrate. The potentiostat monitors the potential between the substrate and the reference electrode. Alternatively, a constant potential can be applied to the substrate and the resulting current measured.

A small currerit is passed at a reasonable voltage. As the various metal oxide species are reduced, the most easily reduced to the most difficult to reduce, the potential first rises to the characteristic reduction potential for that specific metal oxide, then remains constant while that species is completely converted to metal. The potential then rises to the next characteristic potential and continues until all reducible species are converted to metal. This method ensures that all metal oxide species are reduced to their metallic state, maximizing the conductivity of the seed layer. Such method may be performed in a standard electrolytic plating cell after installing an insoluble anode as well as replacing a rectifier with an appropriate potentiostat.

Once any metal oxide on the metal seed layer has been reduced, the substrate is removed from the aqueous solution and rinsed, typically with deionized water. The metal seed layer can then be contacted with a plating bath to provide lateral growth of the seed layer or alternatively, a final metal layer. By “lateral growth” is meant that metal is deposited horizontally along the surface of the seed layer at a rate faster than it is deposited upward from the seed layer. Suitable plating baths include electroless and electrolytic plating baths. Such electrolytic plating baths may be acidic or alkaline. It is preferred that the plating bath is electrolytic, and more preferably an acidic electrolytic plating bath. Any method of enhancing lateral growth to remove or reduce discontinuities may be used advantageously with the cathodic reduction process of the present invention, such as that disclosed in PCT Patent Application number WO 99/47731 (Chen). Any metal that may be deposited electrolessly or electrolytically and is compatible with the underlying seed layer may be used. It is preferred that both the metal seed layer and the final metal layer include the same metal or an alloy thereof. It is further preferred that the final metal layer is copper, and more preferably that the seed layer and final metal layer are both copper.

A wide variety of electroplating solutions may be used to plate metal on the cathodically activated seed layer, i.e. seed layer substantially free of metal oxide. Electroplating solutions useful of the present invention generally include at least one soluble copper salt and an electrolyte. The electroplating solutions may optionally contain one or more additives, such as halides, accelerators or brighteners, suppressors, levelers, grain refiners, wetting agents, surfactants and the like. It is preferred that the electroplating solutions used in the present invention contain one or more suppressors, and more preferably one or more suppressors and one or more accelerators. It is further preferred that the electroplating solutions contain one or more halides.

A variety of copper salts may be employed in the subject electroplating solutions, including for example copper sulfates, copper acetates, copper fluoroborate, and cupric nitrates. Copper sulfate pentahydrate is a particularly preferred copper salt. A copper salt may be suitably present in a relatively wide concentration range in the electroplating compositions of the invention. Preferably, a copper salt will be employed at a concentration of from about 1 to about 300 g/L of plating solution, more preferably at a concentration of from about 10 to about 225 g/L, still more preferably at a concentration of from about 25 to about 175 g/L. The copper plating bath may also contain amounts of other alloying elements, such as, but not limited to, tin, zinc, and the like. Thus, the copper electroplating baths useful in the present invention may deposit copper or copper alloy.

Plating baths useful in the present invention employ an electrolyte, preferably an acidic electrolyte. When the electrolyte is acidic, the acid may be inorganic or organic. Suitable inorganic acids include, but are not limited to, sulfuric acid, phosphoric acid, nitric acid, hydrogen halide acids, sulfamic acid, fluoroboric acid and the like. Suitable organic acids include, but are not limited to, alkylsulfonic acids such as methanesulfonic acid, aryl sulfonic acids such as phenylsulfonic acid and tolylsulfonic acid, carboxylic acids such as formic acid, acetic acid and propionic acid, halogenated acids such as trifluoromethylsulfonic acid and haloacetic acid, and the like. Particularly suitable organic acids include (C₁-C₁₀)alkylsulfonic acids.

Preferred acids include sulfuric acid, nitric acid, methanesulfonic acid, phenylsulfonic acid, mixtures of sulfuric acid and methanesulfonic acid, mixtures of methanesulfonic acid and phenylsulfonic acid, and mixtures of sulfuric acid, methanesulfonic acid and phenylsulfonic acid.

It will be appreciated by those skilled in the art that a combination of two or more acids may be used. Particularly suitable combinations of acids include one or more inorganic acids with one or more organic acids or a mixture of two or more organic acids. Typically, the two or more acids may be present in any ratio. For example, when two acids are used, they may be present in any ratio from 99:1 to 1:99. Preferably, the two acids are present in a ratio from 90:10 to 10:90, more preferably from 80:20 to 20:80, still more preferably from 75:25 to 25:75, and even more preferably from 60:40 to 40:60.

The total amount of added acid used in the present electroplating baths may be from about 0 to about 350 g/L, and preferably from 0 to 225 g/L. It will be appreciated by those skilled in the art that by using a metal sulfate as the metal ion source, an acidic electrolyte can be obtained without any added acid.

For certain applications, such as in the plating of wafers having very small apertures, it is preferred that the total amount of added acid be low. By “low acid” is meant that the total amount of added acid in the electrolyte is less than about 0.4 M, preferably less than about 0.3 M, and more preferably less than about 0.2 M. It is further preferred that the electrolyte is free of added acid.

The electrolyte may optionally contain one or more halides, and preferably does contain at least one halide. Chloride and bromide are preferred halides, with chloride being more preferred. A wide range of halide ion concentrations (if a halide ion is employed) may be suitably utilized, e.g. from about 0 (where no halide ion employed) to 100 ppm of halide ion in the plating solution, more preferably from about 25 to about 75 ppm.

A wide variety of brighteners (or accelerators), including known brightener agents, may be employed in the copper electroplating compositions of the invention. Typical brighteners contain one or more sulfur atoms, and typically without any nitrogen atoms and a molecular weight of about 1000 or less. Brightener compounds that have sulfide and/or sulfonic acid groups are generally preferred, particularly compounds that comprise a group of the formula R′—S—R—SO₃X, where R is an optionally substituted alkyl (which include cycloalkyl), optionally substituted heteroalkyl, optionally substituted aryl group, or optionally substituted heteroalicyclic; X is a counter ion such as sodium or potassium; and R′ is hydrogen or a chemical bond (i.e. —S—R—SO₃X or substituent of a larger compound). Typically alkyl groups will have from one to about 16 carbons, more typically one to about 8 or 12 carbons. Heteroalkyl groups will have one or more hetero (N, O or S) atoms in the chain, and preferably have from 1 to about 16 carbons, more typically 1 to about 8 or 12 carbons. Carbocyclic aryl groups are typical aryl groups, such as phenyl and naphthyl. Heteroaromatic groups also will be suitable aryl groups, and typically contain 1 to about 3 N, O or S atoms and 1-3 separate or fused rings and include e.g. coumarinyl, quinolinyl, pyridyl, pyrazinyl, pyrimidyl, furyl, pyrrolyl, thienyl, thiazolyl, oxazolyl, oxidizolyl, triazole, imidazolyl, indolyl, benzofuranyl, benzothiazol, and the like. Heteroalicyclic groups typically will have 1 to 3 N, O or S atoms and from 1 to 3 separate or fused rings and include e.g. tetrahydrofuranyl, thienyl, tetrahydropyranyl, piperdinyl, morpholino, pyrrolindinyl, and the like. Substituents of substituted alkyl, heteroalkyl, aryl or heteroalicyclic groups include e.g. (C₁-C₈)alkoxy; (C₁-C₈)alkyl, halogen, particularly fluorine, chlorine and bromine; cyano, nitro, and the like.

More specifically, useful brighteners include those of the following formulae:

XO₃—S—R—SH

XO₃S—R—S—S—R—SO₃X and

XO₃S—Ar—S—S—Ar—SO₃X

where in the above formulae R is an optionally substituted alkyl group, and preferably is an alkyl group having from 1 to 6 carbon atoms, more preferably is an alkyl group having from 1 to 4 carbon atoms; Ar is an optionally substituted aryl group such as optionally substituted phenyl or naphthyl; and X is a suitable counter ion such as sodium or potassium.

Some specific suitable brighteners include e.g. n,n-dimethyl-dithiocarbamic acid-(3-sulfopropyl)ester; 3-mercapto-propylsulfonic acid-(3-sulfopropyl)ester; 3-mercapto-propylsulfonic acid (sodium salt); carbonic acid-dithio-o-ethylester-s-ester with 3-mercapto-1-propane sulfonic acid (potassium salt); bissulfopropyl disulfide; 3-(benzthiazolyl-s-thio)propyl sulfonic acid (sodium salt); pyridinium propyl sulfobetaine; 1-sodium-3-mercaptopropane-1-sulfonate; sulfoalkyl sulfide compounds disclosed in U.S. Pat. No. 3,778,357; the peroxide oxidation product of a dialkyl amino-thiox-methyl-thioalkanesulfonic acid; and combinations of the above. Additional suitable brighteners are also described in U.S. Pat. Nos. 3,770,598, 4,374,709, 4,376,685, 4,555,315, and 4,673,469, all incorporated herein by reference. Particularly preferred brighteners for use in the plating compositions of the invention are n,n-dimethyl-dithiocarbamic acid-(3-sulfopropyl)ester and bis-sodium-sulfonopropyl-disulfide.

The amount of such accelerators present in the electroplating baths is in the range of from about 0.1 to about 1000 ppm. Preferably, the accelerator compounds are present in an amount of from about 0.5 to about 300 ppm, more preferably from about 1 to about 100 ppm, still more preferably from about 2 to about 50 ppm, and even more preferably from about 2 to about 30 ppm.

The suppressor agents useful in the compositions of the invention are polymeric materials, preferably having heteroatom substitution, particularly oxygen linkages. Generally preferred suppressor agents are generally high molecular weight polyethers, such as those of the following formula:

R—O—(CXYCX′Y′O)ₙH

where R is an aryl or alkyl group containing from about 2 to 20 carbon atoms; each X, Y, X′ and Y′ is independently hydrogen, alkyl preferably methyl, ethyl or propyl, aryl such as phenyl; aralkyl such as benzyl; and preferably one or more of X, Y, X′ and Y′ is hydrogen; and n is an integer between 5 and 100,000. Preferably, R is ethylene and n is greater than 12,000.

The amount of such suppressors present in the electroplating baths is in the range of from about 0.1 to about 1000 ppm. Preferably, the suppressor compounds are present in an amount of from about 100 to about 800 ppm, and more preferably from about 150 to about 700 ppm.

Surfactants may optionally be added to the electroplating baths. Such surfactants are typically added to copper electroplating solutions in concentrations ranging from about 1 to 10,000 ppm based on the weight of the bath, more preferably about 5 to 10,000 ppm. Particularly suitable surfactants for plating compositions of the invention are commercially available polyethylene glycol copolymers, including polyethylene glycol copolymers. Such polymers are available from e.g. BASF (sold by BASF under TETRONIC and PLURONIC tradenames), and copolymers from Chemax. A butylalcohol-ethylene oxide-propylene oxide copolymer having a molecular weight of about 1800 from Chemax is particularly preferred. Branched polymeric suppressors are more preferred.

Levelers may optionally be added to the present electroplating baths. It is preferred that one or more leveler components is used in the present electroplating baths. Such levelers may be used in amounts of from about 0.01 to about 50 ppm. Examples of suitable leveling agents are described and set forth in U.S. Pat. Nos. 3,770,598, 4,374,709, 4,376,685, 4,555,315 and 4,673.459. In general, useful leveling agents include those that contain a substituted amino group such as compounds having R—N—R′, where each R and R′ is independently a substituted or unsubstituted alkyl group or a substituted or unsubstituted aryl group. Typically the alkyl groups have from 1 to 6 carbon atoms, more typically from 1 to 4 carbon atoms. Suitable aryl groups include substituted or unsubstituted phenyl or naphthyl. The substituents of the substituted alkyl and aryl groups may be, for example, alkyl, halo and alkoxy.

More specifically, suitable leveling agents include, but are not limited to, 1-(2-hydroxyethyl)-2-imidazolidinethione; 4-mercaptopyridine; 2-mercaptothiazoline; ethylene thiourea; thiourea; alkylated polyalkyleneimine; phenazonium compounds disclosed in U.S. Pat. No. 3,956,084; N-heteroaromatic rings containing polymers; quaternized, acrylic, polymeric amines; polyvinyl carbamates; pyrrolidone; and imidazole. A particularly preferred leveler is 1-(2-hydroxyethyl)-2-imidazolidinethione.

Thus, the present invention provides a method for manufacturing an electronic device comprising the steps of: a) contacting a metal seed layer containing oxidized metal disposed on a substrate with an aqueous solution having a pH maintained in the range of about 6.5 to about 13; b) subjecting the solution to a voltage of from about 0.1 to 5 volts to reduce the oxidized metal; c) monitoring the reduction of the oxidized metal to provide a substantially metal oxide free seed layer; and d) contacting the substantially metal oxide free seed layer with an electroplating bath.

The present invention is particularly suitable for reducing metal oxide on seed layers on substrates having small apertures, and preferably very small apertures, such as those with aspect ratios of 1:1 to 10:1, and preferably 4:1 to 10:1.

Accordingly, the present invention also provides an article of manufacture including an electronic device substrate containing one or more apertures, each aperture containing an electrolytic copper deposit on a seed layer treated according to the above described method.

The present invention further provides a method for manufacturing an electronic device including the step of monitoring the oxidation state of metal in a seed layer deposited on a substrate. Preferably, the oxidation state is monitored through the use of a potentiostat, and more preferably by a SERA technique. Such method is particularly suitable for the manufacture of integrated circuits. Suitable substrates include wafers, particularly barrier layers, and preferably barrier layers on dielectric layers on wafers.

Once a semiconductor wafer is plated, the wafer is preferably subjected to chemical-mechanical planarization (“CMP”). A CMP procedure can be conducted in accordance with the invention as follows.

The wafer is mounted in a wafer carrier which urges the wafer against the surface of a moving polishing pad. The polishing pad can be a conventional smooth polishing pad or a grooved polishing pad. Examples of a grooved polishing pad are described in U.S. Pat. Nos. 5,177,908; 5,020,283; 5,297,364; 5,216,843; 5,329,734; 5,435,772; 5,394,655; 5,650,039; 5,489,233; 5,578,362; 5,900,164; 5,609,719; 5,628,862; 5,769,699; 5,690,540; 5,778,481; 5,645,469; 5,725,420; 5,842,910; 5,873,772; 5,921,855; 5,888,121; 5,984,769; and European Patent 806267. The polishing pad can be located on a conventional platen can rotate the polishing pad. The polishing pad can be held on the platen by a holding means such as, but not limited to, an adhesive, such as, two faced tape having adhesive on both sides.

A polishing solution or slurry is fed onto the polishing pad. The wafer carrier can be at a different positions on the polishing pad. The wafer can be held in position by any suitable holding means such as, but is not limited to, a wafer holder, vacuum or liquid tensioning such as, but not limited to a fluid such as, but not limited to water. If the holding means is by vacuum then there is preferably a hollow shaft which is connected to the wafer carrier. Additionally, the hollow shaft could be used to regulate gas pressure, such as, but not limited to air or an inert gas or use a vacuum to initially hold the wafer. The gas or vacuum would flow from the hollow shaft to the carrier. The gas can urge the wafer against the polishing pad for the desired contour. The vacuum can initially hold the wafer into position in the wafer carrier. Once the wafer is located on top of the polishing pad the vacuum can be disengaged and the gas pressure can be engaged to thrust the wafer against the polishing pad. The excess or unwanted copper is then removed. The platen and wafer carrier can be independently rotatable. Therefore, it is possible to rotate the wafer in the same direction as the polishing pad at the same or different speed or rotate the wafer in the opposite direction as the polishing pad.

Thus, the present invention provides a method for removing excess material from a semiconductor wafer by using a chemical mechanical planarization process which includes contacting the semiconductor wafer with a rotating polishing pad thereby removing the excess material from the semiconductor wafer; wherein the semiconductor wafer has been prior electroplated by a copper electroplating composition according to the method including the steps of: a) contacting a metal seed layer containing oxidized metal disposed on a substrate with an aqueous solution having a pH maintained in the range of about 6.5 to about 13; b) subjecting the solution to a voltage of from about 0.1 to 5 volts to reduce the oxidized metal; c) monitoring the reduction of the oxidized metal to provide a substantially metal oxide free seed layer; and d) contacting the substantially metal oxide free seed layer with a copper electroplating bath.

Also provided is a method for removing excess material from a semiconductor wafer by using a chemical mechanical planarization process which includes contacting the semiconductor wafer with a rotating polishing pad thereby removing the excess material from the semiconductor wafer; wherein the semiconductor wafer contains a seed layer having been prior repaired according to the method described above prior to electroplating.

While the present invention has been described with respect to copper electroplating baths, it will be appreciated by those skilled in the art that the present mixed acid electrolyte may be used with a variety of plating baths, such as tin, tin alloy, nickel, nickel-alloy, and the like.

The following examples are presented to illustrate further various aspects of the present invention, but are not intended to limit the scope of the invention in any aspect.

### EXAMPLE

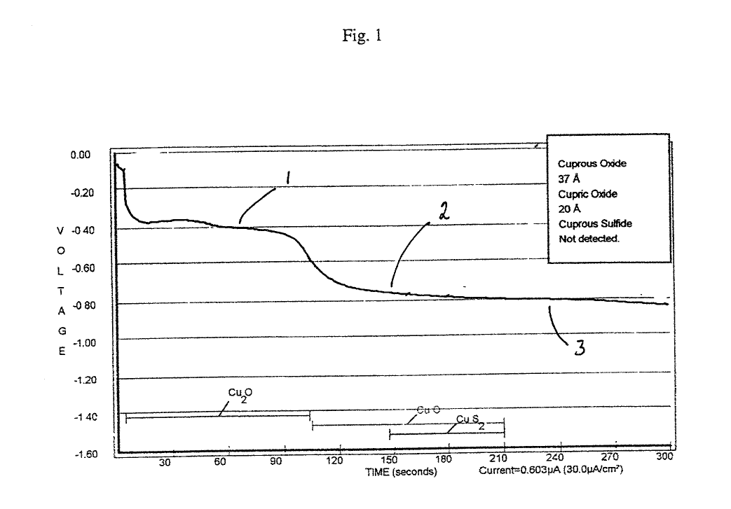

An electrolyte composition was prepared by combining 6.18 g/L boric acid, 9.55 g/L sodium borate and deionized water to 1 liter. An old QCE wafer containing an oxidized copper seed layer was placed in the electrolyte. A constant current of 30 μA/cm² was applied using a QC-100™ Surface Scan instrument. FIG. 1 shows a plot of voltage versus time for this cathodic activation treatment. Referring to FIG. 1, the first oxide species to be reduced is Cu₂O as indicated by region 1, the second oxide species reduced is CuO as indicated by region 2 with all oxide being reduced to copper metal by 210 seconds at region 3.

What is claimed is:

1. A method of removing oxidized metal from a metal seed layer comprising the steps of: a) contacting a metal seed layer containing oxidized metal disposed on a substrate with an aqueous solution having a pH maintained in the range of about 6.5 to about 13; b) subjecting the solution to a voltage of from about 0.1 to 5 volts to reduce the oxidized metal; and c) monitoring the reduction of the oxidized metal to provide a seed layer substantially free of all oxidized metal species.

2. The method of claim 1 wherein the pH is maintained by a buffer.

3. The method of claim 2 wherein the buffer comprises phosphate, boric acid/borate, tris(hydroxymethyl)aminomethane hydrohalide salt or carbonate.

4. The method of claim 1 wherein the pH of the aqueous solution is maintained in the range of about 7 to about 10.

5. The method of claim 1 wherein the metal seed layer comprises copper or copper alloys.

6. The method of claim 1 wherein the voltage is in the range of 0.2 to 5 volts.

7. The method of claim 6 wherein the voltage is in the range of 1 to 5 volts.

8. The method of claim 1 wherein the voltage is applied to the metal seed layer for 5 to 300 seconds.

9. The method of claim 1 wherein the substrate is selected from semiconductor wafers and dielectric layers.

10. The method of claim 1 wherein a potentiostat is used to monitor the reduction of the oxidized metal.

11. A method for manufacturing an electronic device comprising the steps of: a) contacting a metal seed layer containing oxidized metal disposed on a substrate with an aqueous solution having a pH maintained in the range of about 6.5 to about 13; b) subjecting the solution to a voltage of from about 0.1 to 5 volts to reduce the oxidized metal; c) monitoring the reduction of the oxidized metal to provide a substantially metal oxide free seed layer; and d) contacting the substantially metal oxide free seed layer with an electroplating bath.

12. The method of claim 11 wherein the pH is maintained by a buffer.

13. The method of claim 12 wherein the buffer comprises phosphate, boric acidiborate, tris(hydroxymethyl)aminomethane hydrohalide salt or carbonate.

14. The method of claim 11 wherein the pH of the aqueous solution is maintained in the range of about 7 to about 10.

15. The method of claim 11 wherein the metal seed layer comprises copper or copper alloys.

16. The method of claim 11 wherein the voltage is in the range of 0.2 to 5 volts.

17. The method of claim 11 wherein the voltage is in the range of 1 to 5 volts.

18. The method of claim 11 wherein the voltage is applied to the metal seed layer for 5 to 300 seconds.

19. The method of claim 11 wherein the electroplating bath comprises a source of copper ions, an electrolyte and optionally one or more accelerators, suppressors or levelers.

20. The method of claim 11 wherein a potentiostat is used to monitor the reduction of the oxidized metal.

21. A method for manufacturing an electronic device comprising the step of monitoring the oxidation state of metal in a seed layer deposited on a substrate.

22. The method of claim 22 wherein a potentiostat is used to monitor the oxidation state of the metal.

23. The method of claim 21 wherein the electronic device is an integrated circuit.

24. The method of claim 21 wherein the substrate is a barrier layer.
